(19) United States
(12) Patent Application Publication
(10) Pub. No.: US 2020/0395259 A1
(43) Pub. Date: Dec. 17, 2020

(54) SEMICONDUCTOR DEVICE

(71) Applicant: DENSO CORPORATION, Kariya-city (JP)

(72) Inventor: Syuhei Miyachi, Kariya-city (JP)

(21) Appl. No.: 16/891,987

(22) Filed: Jun. 3, 2020

(30) Foreign Application Priority Data
Jun. 11, 2019 (JP) 2019-108846

(51) Int. Cl. H01L 23/31; H01L 23/495; H05K 3/34; H01L 23/00

(52) U.S. Cl. CPC H01L 23/3107; H01L 23/49548; H05K 3/3426; H01L 2224/32245; H01L 24/05; H01L 2224/05599; H01L 24/32

(57) ABSTRACT

A semiconductor device is to be mounted on a mount object by a solder. The semiconductor device includes a semiconductor element, an insulation member, and a plurality of terminals. The semiconductor element includes a plurality of electrodes. The insulation member covers the semiconductor element. The plurality of terminals is electrically connected to the plurality of electrodes. At least a part of the plurality of terminals is exposed outside the insulation member.

### CROSS REFERENCE TO RELATED APPLICATION

The present application claims the benefit of priority from Japanese Patent Application No. 2019-108846 filed on Jun. 11, 2019. The entire disclosure of the above application is incorporated herein by reference.

### TECHNICAL FIELD

The present disclosure relates to a semiconductor device.

### BACKGROUND

In order to mount a semiconductor chip on a substrate, a terminal of the semiconductor chip is soldered to a circuit of the substrate. A technique that improve bonding strength between the terminal and the circuit has been proposed.

### SUMMARY

The present disclosure provides a semiconductor device. The semiconductor device is to be mounted on a mount object by a solder. The semiconductor device includes a semiconductor element, an insulation member, and a plurality of terminals. The semiconductor element includes a plurality of electrodes. The insulation member covers the semiconductor element. The plurality of terminals is electrically connected to the plurality of electrodes. At least a part of the plurality of terminals is exposed outside the insulation member.

### BRIEF DESCRIPTION OF DRAWINGS

The features and advantages of the present disclosure will become more apparent from the following detailed description made with reference to the accompanying drawings. In the drawings:

FIG. 1 is a cross-sectional view showing a semiconductor device of a first embodiment;

FIG. 2 is a side view showing the semiconductor device;

FIG. 3 is a plan view showing the semiconductor device;

FIG. 4 is a bottom view showing the semiconductor device;

FIG. 5 is an enlarged cross-sectional view showing the semiconductor device;

FIG. 6 is a bottom view showing another example of the semiconductor device;

FIG. 7 is a bottom view showing still another example of the semiconductor device;

FIG. 8 is a plan view showing a semiconductor device of a second embodiment;

FIG. 9 is a cross-sectional view showing the semiconductor device;

FIG. 10 is a bottom view showing the semiconductor device; and

FIG. 11 is a cross-sectional view showing a semiconductor device of a third embodiment.

### DETAILED DESCRIPTION

When a semiconductor device such as a semiconductor chip is mounted on a mount object such as a circuit board, a portion that requires the highest bonding strength is a bonding portion between a terminal of the semiconductor chip and the circuit board.

For example, in a semiconductor device, a groove is formed on a side surface of the terminal, and a plating is applied to the groove. The groove is easily wetted by solder. When the semiconductor chip having such a terminal is soldered to the circuit board, the solder rises in the groove. This configuration improves bonding strength between the terminal and the circuit board. However, for example, when the terminal is mounted on a vehicle and used in a severe temperature cycle, the bonding strength may be insufficient.

The present disclosure provides a semiconductor device which can improve bonding strength with a mount object.

An example embodiment of the present disclosure provides a semiconductor device to be mounted on a mount object by a solder. The semiconductor device includes a semiconductor element, an insulation member, and a plurality of terminals. The semiconductor element includes a plurality of electrodes. The insulation member covers the semiconductor element. The plurality of terminals is electrically connected to the plurality of electrodes. At least a part of the plurality of terminals is exposed outside the insulation member. Each of the plurality of terminals has a lower surface to be connected to the mount object. At least one of the plurality of terminals includes a recess or a protrusion on the lower surface.

In the example embodiment of the present disclosure, the at least one of the plurality of terminals includes the recess or the protrusion on the lower surface. Thus, the area of the surface in the configuration can be greater than that of a flat surface. When the surface area is increased, the area where the terminal and the mount object are joined via the solder is increased. Thus, the bonding strength can be improved. The configuration makes it possible to improve the connection reliability even in a severe temperature cycle.

The following describes embodiments for carrying out the present disclosure with reference to the drawings. In each embodiment, a part corresponding to the part described in the preceding embodiment may be denoted by the same reference symbol or a reference symbol with one character added to the preceding reference symbol; thereby, redundant explanation may be abbreviated. In each embodiment, when only part of the configuration is described, the other part of the configuration can be the same as that in the preceding embodiment described above. The present disclosure is not limited to combinations of embodiments which combine parts that are explicitly described as being combinable. As long as no problems are present, the various embodiments may be partially combined with each other even if not explicitly described.

### First Embodiment

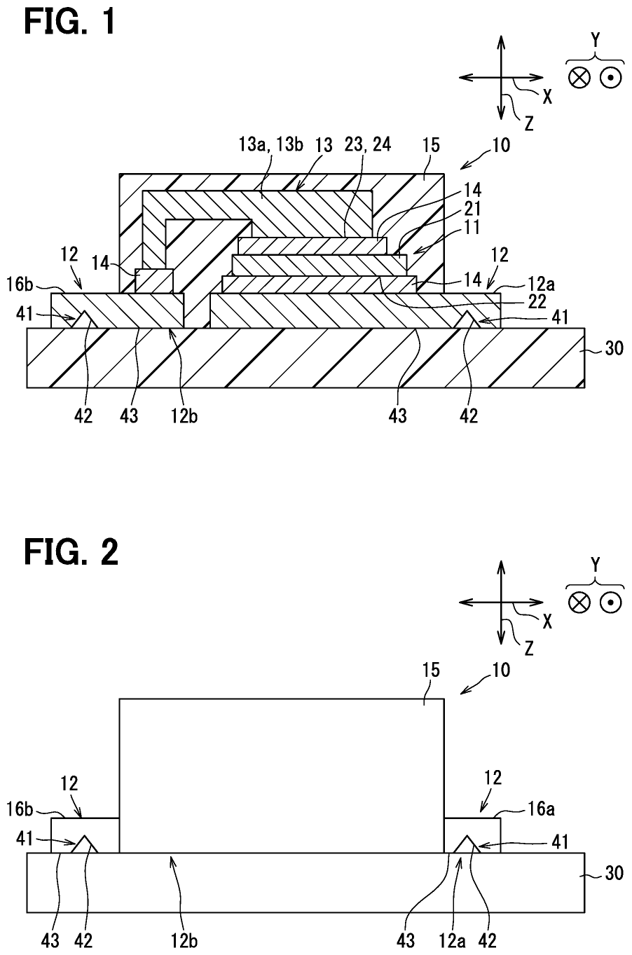

Hereinafter, a first embodiment of the present disclosure will be described with reference to FIGS. 1 to 7. A semiconductor device 10 shown in FIG. 1 is mounted on a circuit board 30 such as an automobile or an electronic device. The semiconductor device 10 may be used for an electric power steering system. The semiconductor device 10 includes a semiconductor element 11, a plurality of terminals 12, a plurality of conductive members 13, a connection member 14, and a resin package 15.

The semiconductor element 11 is an electronic component that provides a main function of the semiconductor device 10. In the present embodiment, the semiconductor element 11 is provided by a power MOSFET (Metal Oxide Semiconductor Field Effect Transistor) which is a power semiconductor element.

Alternatively, the semiconductor element 11 may be provided by another power semiconductor element, for example, an IGBT (Insulated Gate Bipolar Transistor). The semiconductor element 11 is not limited thereto, and may be provided by another transistor, such as, a diode, a thyristor, or the like. The semiconductor element 11 may be provided by an IC chip, such as a control IC.

The semiconductor element 11 includes an element body 21, a first electrode 22, a second electrode 23, and a third electrode 24. The element body 21 is made of a semiconductor material, for example, silicon. The element body 21 has a rectangular parallelepiped shape.

The first electrode 22, the second electrode 23, and the third electrode 24 each has a plating layer of, for example, Cu, Ni, Al, Au, or the like. In the present embodiment, since the semiconductor element 11 is provided by a power MOSFET, the first electrode 22 functions as a drain electrode, the second electrode 23 functions as a gate electrode, and the third electrode 24 functions as a source electrode. When the semiconductor element 11 may be provided by an IGBT, the first electrode 22 functions as a collector electrode, the second electrode 23 functions as a gate electrode, and the third electrode 24 functions as an emitter electrode.

The first electrode 22 is formed on a lower surface of the element body 21. The first electrode 22 covers the entire lower surface of the element body 21. The second electrode 23 and the third electrode 24 are formed on an upper surface of the element body 21. Area of the second electrode 23 is smaller than area of the third electrode 24.

The plurality of conductive members 13 include a first conductive member 13a and a second conductive member 13b. Each of the first conductive member 13a and the second conductive member 13b is made of a conductive material. The first conductive member 13a is electrically and mechanically connected to the second electrode 23 via the connection member 14. The plurality of second conductive members 13b are electrically and mechanically connected to the third electrode 24 via the connection member 14.

The terminal 12 forms a conduction path between the semiconductor element 11 and the circuit board 30 by being joined to the circuit board 30 as a mount object. The terminal 12 is made of a conductive material, for example, Cu. The plurality of terminals 12 includes a first terminal 12a, a second terminal 12b, and a third terminal 12c. In each of the first terminal 12a, the second terminal 12b, and the third terminal 12c, a portion exposed from the resin package 15 is covered with metal plating. The metal plating may be Ag, and is formed by, for example, electrolytic plating. In each of the first terminal 12a, the second terminal 12b, and the third terminal 12c, plating layer is formed on a portion that is electrically connected to another member.

The first terminal 12a is electrically connected to the first electrode 22 by the connection member 14. The connection member 14 may be provided by solder. The first terminal 12a has a flat upper surface, and a plating layer is formed on the upper surface. The plating layer covers a portion of the upper surface of the first terminal 12a on which the semiconductor element 11 is mounted. The plating layer may be made of Ag. The plating layer may be formed by electrolytic plating.

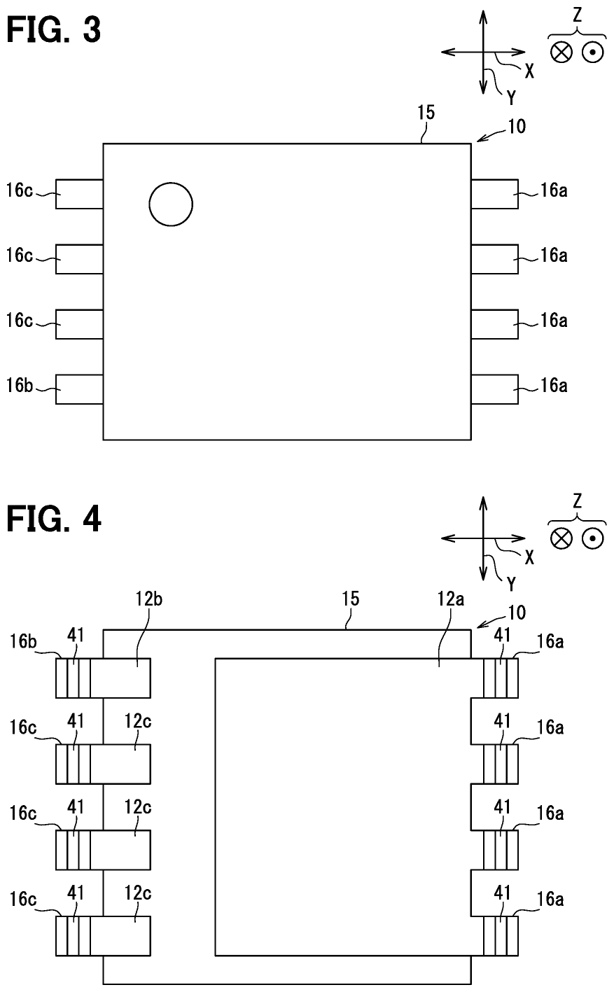

A lower surface of the first terminal 12a is exposed from the resin package 15 over the entire surface. With this configuration, heat dissipation of the semiconductor device 10 is improved. The lower surface of the first terminal 12a may be covered with the resin package 15. The first terminal 12a includes a plurality of projections 16a. As shown in FIG. 3, the plurality of projections 16a protrude outward from the resin package 15.

The second terminal 12b is electrically connected to the second electrode 23 via the first conductive member 13a. The third terminal 12c is electrically connected to the third electrode 24 via the second conductive member 13b. The second terminal 12b is electrically and mechanically connected to the first conductive member 13a via the connection member 14. Similarly, the third terminal 12c is electrically and mechanically connected to the second conductive member 13b via the connection member 14.

Each of the second terminal 12b and the third terminal 12c has a flat upper surface, and a plating layer is formed on the upper surface. A lower surface of each of the second terminal 12b and the third terminal 12c is exposed from the resin package 15 over the entire surface. The second terminal 12b has one projection 16b. The projection 16b extends outside the resin package 15 so as to protrude in an opposite direction to which the projection 16a of the first terminal 12a extends. The third terminal 12c has a plurality of projections 16c. The plurality of projections 16c extend outside the resin package 15 so as to protrude in the same direction to which the projection 16b of the second terminal 12b extends.

The resin package 15 is provided by an insulation member that covers the semiconductor element 11, a part of the terminal 12, the connection member 14, and the conductive member 13. The resin package 15 is made of a thermosetting synthetic resin having an electrical insulation property. The resin package 15 may be made of a black epoxy resin.

Next, the shape of the lower surface of the terminal 12 will be described. Hereinafter, a direction to which the terminals 12 extend is referred to as a longitudinal direction X (left and right direction in FIG. 4), a direction perpendicular to the longitudinal direction X is referred to as a width direction Y (up and down direction in FIG. 4), and a direction perpendicular to the longitudinal direction X and the width direction Y is referred to as an up and down direction Z (up and down direction in FIG. 1). Each of the projections 16c of the terminal 12 corresponds to a longitudinal member extending in the longitudinal direction X.

As shown in FIGS. 1 and 2, a recess 41 having a recessed shape is partially provided in a connection portion with the circuit board 30 on the lower surface of each of the projections 16c of the terminal 12. The lower surface of the terminal 12 is a surface facing the circuit board 30. The recess 41 is formed in the projection 16 of each of the plurality of terminals 12. The projection 16 protrudes from the resin package 15 in the longitudinal direction X. Therefore, the recess 41 is located outside a projection area of the resin package 15 projected in the up and down direction Z.

The recess 41 is a portion that forms an inner surface 42. The outer surface 43 of the terminal 12 is an outer peripheral surface excluding the upper surface and the lower surface when the terminal 12 has no recess. The inner surface 42 is a surface formed as a surface different from the lowermost surface of the terminal 12 by forming a recess in the terminal 12.

As shown in FIG. 1, the recess 41 is a groove having a triangular shape in the cross-sectional view. As shown in FIG. 4, the recess 41 extends in the width direction Y. The recess 41 reaches both ends of the terminal 12 in the width direction Y. In other words, the recess 41 is connected to the outer surface 43 in the width direction Y. In the present embodiment, the recess 41 extends in the width direction Y, but is not limited to the width direction Y. Alternatively, the recess 41 may be any direction that intersects the longitudinal direction X.

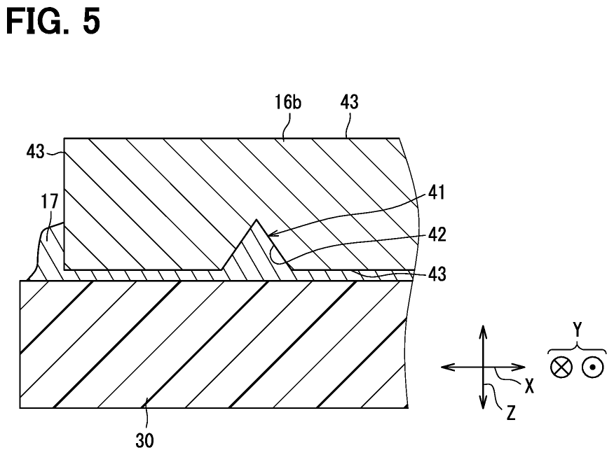

The recess 41 is formed so that the surface area of the lower surface of the terminal 12 increases. Therefore, as shown in FIG. 5, when the semiconductor device 10 is mounted on the circuit board 30 by the solder 17, the solder 17 enters the recess 41 to be able to increase the connection area of the solder 17.

The dimension of the recess 41 in the longitudinal direction X is preferably half the length of the projection 16c, more preferably ⅓ or less. When the dimension of the recess 41 in the longitudinal direction X is too large, the strength of the projection 16c and the conductivity of the projection 16c may be reduced. Therefore, it is preferable to select the dimension described above.

The dimension of the recess 41 in the up and down direction Z is preferably half the height of the projection 16c, more preferably ⅓ or less. When the dimension of the recess 41 in the up and down direction Z is too large, the strength of the projection 16c and the conductivity of the projections 16c may be reduced. Therefore, it is preferable to select the dimension described above.

As described above, in the semiconductor device 10 of the present embodiment, the contact portion of the lower surface of the terminal 12 contacting the circuit board 30 includes the recess 41. Thus, the terminal 12 with the above-described configuration can have the larger surface area than a terminal having a flat shape. When the surface area is increased, the area where the terminal 12 and the circuit board 30 are joined via the solder 17 is increased. Thus, the bonding strength can be improved. The configuration makes it possible to improve the connection reliability even in a severe temperature cycle, such as, in a vehicle.

In the present embodiment, the projection 16c of the terminal 12 is a longitudinal member extending in the longitudinal direction X. The recess 41 extends in the width direction Y and reaches the both ends of the terminal 12 in the width direction Y. When the terminal 12 is joined to the circuit board 30 via the solder 17, a void may be generated in the solder 17. Since the recess 41 reaches the both ends in the width direction Y, the void can be released from the both ends in the width direction Y. This configuration can reduce the possibility that the void is formed.

In the present embodiment, the recess 41 is formed on the lower surface of the projection 16c of each terminal 12. However, the present embodiment is not limited to such a configuration. The recess 41 may be formed on the projection 16 of one terminal 12. Preferably, a recess is formed on the lower surface of the projection 16b of the second terminal 12b connected to the gate electrode. The second terminal 12b is a terminal 12 having a smaller number of projection 16b and a smaller bonding area with the circuit board 30 than the first terminal 12a and the third terminal 12c. In order to improve the bonding strength of the terminal 12, it is preferable to form a recess in the second terminal 12b. Further, since the recess is formed in the second terminal 12b, the manufacturing cost can be reduced as compared with the case where the other terminals 12 have respective recesses.

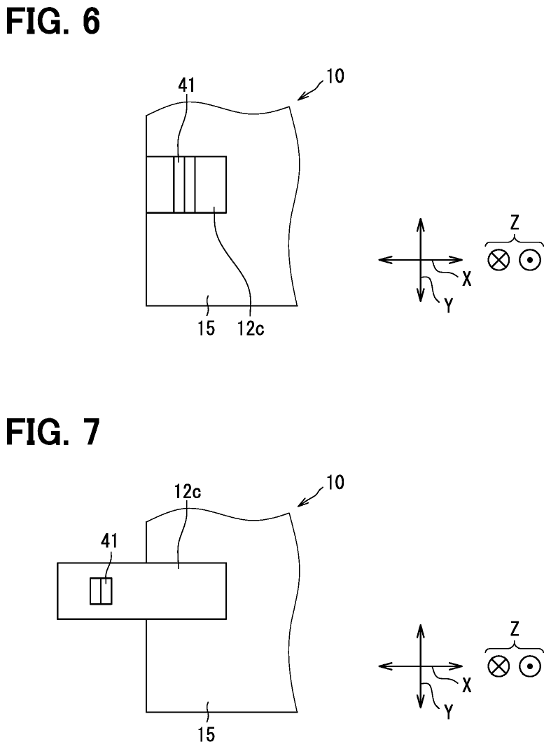

Further, in the present embodiment, the recess 41 is located outside the resin package 15. However, the present embodiment is not limited to such a configuration. For example, as shown in FIG. 6, when the terminal 12 is located inside the resin package 15, the recess 41 may be formed inside the outer periphery of the resin package 15. In other words, the terminal 12 may be arranged in the projection area where the resin package 15 projects in the up and down direction Z, and the recess 41 may be arranged in the projection area.

Further, in the present embodiment, the recess 41 is formed to extend to the ends in the width direction Y, but is not limited to such a configuration. For example, as shown in FIG. 7, the recess 41 may be formed in an island shape so as not to reach the outer peripheral portion of the terminal 12.

### Second Embodiment

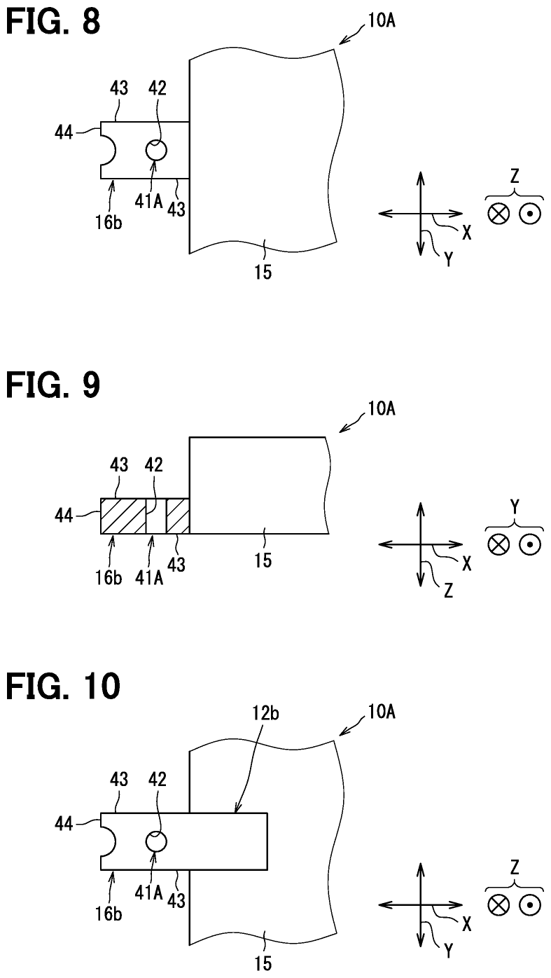

Hereinafter, a second embodiment of the present disclosure will be described with reference to FIGS. 8 to 10. In a semiconductor device 10A of the present embodiment, a recess penetrates from the lower surface of the terminal 12 to the upper surface of the terminal 12. Also, a distal end surface 44 of the projection 16 is recessed.

As shown in FIG. 9, the recess 41A is constituted by a through hole. Since such a recess 41A also has the inner surface 42, the bonding area of the solder 17 can be increased similarly to the first embodiment. Furthermore, since the recess 41A penetrates in the up and down direction Z, the void can be released from the upper surface of the terminal 12 without remaining in the recess. The present configuration enables to reduce the generation of the void.

As shown in FIGS. 8 and 9, the distal end surface 44 located at the distal end of the projection 16 in the longitudinal direction X is partially recessed. In other words, the distal end surface 44 of the terminal 12 is not flat but recessed. A plating layer is formed on the inner surface 42. The configuration enables the solder 17 to be easily wetted. Thus, when joining is performed using the solder 17, the solder 17 is also provided in the recess of the distal end surface 44. Therefore, the bonding area of the solder 17 can be further increased.

### Third Embodiment

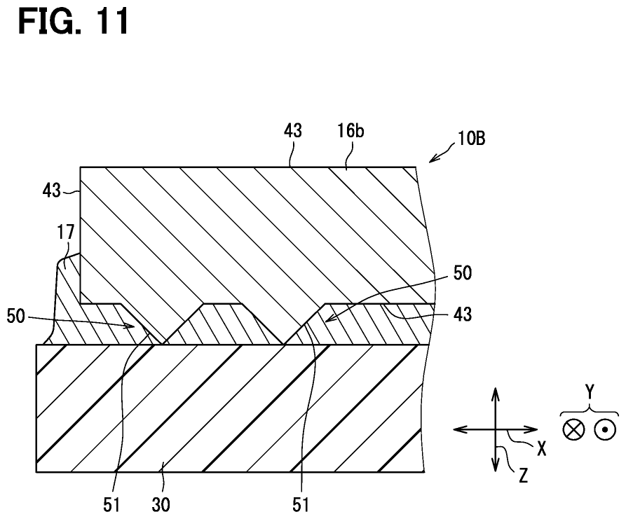

Hereinafter, a third embodiment of the present disclosure will be described with reference to FIG. 11. In a semiconductor device 10B of the present embodiment, a protrusion instead of a recess is partially formed on the lower surface of the terminal 12.

As shown in FIG. 11, on the lower surface of the projection 16c of the terminal 12, there is a protrusion 50 having a protruded shape at a connection portion with the circuit board 30. The protrusion 50 forms a protrusion surface 51. The protrusion surface 51 is a surface formed as a surface different from the lower surface of the terminal 12 by forming a protrusion in the terminal 12. As shown in FIG. 11, the protrusion 50 has a triangular shape in the cross-sectional view. A plurality of conical protrusions 50 are formed on the lower surface of the terminal 12. Therefore, the protrusions 50 do not extend to both ends in the width direction Y, and are independently arranged to be interspersed.

The protrusion 50 is formed so that the surface area of the lower surface of the terminal 12 increases. Therefore, as shown in FIG. 11, when the semiconductor device 10 is mounted on the circuit board 30 by the solder 17, the solder 17 flows in the periphery of the protrusion 50 to be able to increase the connection area of the solder 17. Further, the protrusion 50 makes the distance between the lower surface of the terminal 12 and the circuit board 30 long. As a result, more solder 17 flows between the lower surface of the terminal 12 and the circuit board 30. Thus, the bonding strength can be further improved.

In addition, the protrusion 50 partially increases the dimension of the terminal 12 in the up and down direction Z. Therefore, the strength of the terminal 12 can be increased.

### Other Embodiments

Although preferred embodiments of the present disclosure have been described above, the present disclosure is not limited to the above-described embodiments, and various modifications are contemplated as exemplified below.

It should be understood that the configurations described in the above-described embodiments are example configurations, and the present disclosure is not limited to the foregoing descriptions. The scope of the present disclosure encompasses claims and various modifications of claims within equivalents thereof.

In the first embodiment described above, the mount object is provided by the circuit board 30. However, the mount object is not limited to the circuit board 30. The mount object may be provided by another electronic device. A terminal of another semiconductor device may be joined to the circuit board 30 by the solder.

In the above-described first embodiment, the terminal 12 is the longitudinal member, but is not limited to such a configuration, and may have a circular shape or a square shape.

In the above-described first embodiment, the recess is formed, and in the third embodiment, the protrusion is formed. However, the configuration is not limited thereto. Both a recess and a protrusion may be formed in one terminal 12.

What is claimed is:

1. A semiconductor device to be mounted on a mount object by a solder, the semiconductor device comprising:
a semiconductor element that includes a plurality of electrodes;
an insulation member that covers the semiconductor element; and
a plurality of terminals electrically connected to the plurality of electrodes, and at least a part of the plurality of terminals exposed outside the insulation member, wherein:
each of the plurality of terminals has a lower surface to be connected to the mount object; and
at least one of the plurality of terminals includes a recess or a protrusion on the lower surface.

2. The semiconductor device according to claim 1, wherein:
each of the plurality of terminals is provided by a longitudinal member; and
the recess or the protrusion extends in a width direction that intersects a longitudinal direction of the at least one of the plurality of terminals to reach both ends of the at least one of the plurality of terminals.

3. The semiconductor device according to claim 1, wherein:
the at least one of the plurality of terminals includes at least the recess on the lower surface; and
the recess penetrates the at least one of the plurality of terminals from the lower surface to an upper surface of the at least one of the plurality of terminals opposite to the lower surface.

4. The semiconductor device according to claim 1, wherein:
the semiconductor element is provided by a field-effect transistor;
the plurality of electrodes includes a gate electrode, a drain electrode, and a source electrode; and
the recess or the protrusion is formed on the lower surface of the terminal electrically connected to the gate electrode.

5. The semiconductor device according to claim 1, wherein:
the semiconductor element is provided by a field-effect transistor;
the plurality of electrodes includes a gate electrode, a drain electrode, and a source electrode; and
the recess or the protrusion is formed only on the lower surface of the terminal electrically connected to the gate electrode.
